(19) United States
(12) Patent Application Publication
(10) Pub. No.: US 2025/0247078 A1
(43) Pub. Date: Jul. 31, 2025

(54) HYBRID LATTICE FILTER

(71) Applicant: Qorvo US, Inc., Greensboro, NC (US)

(72) Inventor: Yazid Yusuf, Orlando, FL (US)

(21) Appl. No.: 19/032,774

(22) Filed: Jan. 21, 2025

Related U.S. Application Data
(60) Provisional application No. 63/626,706, filed on Jan. 30, 2024.

(51) Int. Cl. H03H 9/54; H03H 9/00; H03H 9/02

(52) U.S. Cl. CPC H03H 9/542; H03H 9/0014; H03H 9/02125

(57) ABSTRACT

Hybrid lattice filters are disclosed. In one aspect, a filter may be formed from a plurality of acoustic resonators and associated inductors. The inductors may be arranged such that they approach an ideal transformer to provide desired out of band rejection. Multiple stages of resonator structures may be chained together to form a filter with a desired response.

### PRIORITY APPLICATION

The present application claims priority to U.S. Provisional Patent Application Ser. No. 63/626,706, filed on Jan. 30, 2024, and entitled “HYBRID LATTICE FILTER,” the contents of which are incorporated herein by reference in its entirety.

### BACKGROUND

### I. Field of the Disclosure

The technology of the disclosure relates generally to filters used in communication devices and particularly to a hybrid lattice filter with improved rejection characteristics.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to provide more bandwidth to send and receive data. Responsive to this pressure, the evolving wireless standards have progressed to ever higher frequencies. While conceptually these higher frequencies satisfy the need for increased bandwidth, these higher frequencies pose new challenges to the hardware, and particularly for filters, being used to transmit and receive such signals. Accordingly, there is room for innovation in the filters being designed for use with emerging technologies.

### SUMMARY

Aspects disclosed in the detailed description include hybrid lattice filters. In particular, a filter may be formed from a plurality of acoustic resonators and associated inductors. The inductors may be arranged such that they approach an ideal transformer to provide desired out-of-band rejection. Multiple stages of resonator structures may be chained together to form a filter with a desired response.

In this regard, in one aspect, a filter is disclosed. The filter includes an input node, an output node, and a first acoustic resonator coupled to the input node. The filter also includes a first inductor coupled to the input node and electrically parallel to the first acoustic resonator, a second inductor coupled to the output node and mutually coupled to the first inductor, but electrically isolated therefrom, and a second acoustic resonator serially coupled to the first acoustic resonator and a ground.

In another aspect, a method of operating a filter is disclosed. The method includes providing a signal to an input node, filtering the signal with a plurality of acoustic resonators, and using shielded mutually coupled inductors to circumvent out-of-band rejection limitations on the signal.

In another aspect, a communication device is disclosed. The communication device includes a transceiver comprising a filter, the filter comprising an input node, an output node, and a first acoustic resonator coupled to the input node. The filter further includes a first inductor coupled to the input node and electrically parallel to the first acoustic resonator, a second inductor coupled to the output node and mutually coupled to the first inductor, but electrically isolated therefrom, and a second acoustic resonator serially coupled to the first acoustic resonator and a ground.

### BRIEF DESCRIPTION OF THE DRAWINGS

FIG. 1A is a block diagram of a lattice filter topology;

FIG. 1B is a block diagram of an equivalent balanced bridge form of the lattice filter of FIG. 1A;

FIG. 2A illustrates operation of the lattice filter of FIG. 1B in a stopband frequency;

FIG. 2B illustrates operation of the lattice filter of FIG. 1B in a passband frequency;

FIG. 3 illustrates a lattice filter with an ideal transformer to operate in an unbalanced mode;

FIG. 4 is a block diagram of a hybrid lattice topology equivalent to the lattice filter of FIG. 1A using an ideal transformer;

FIG. 5A is a circuit diagram of two mutually coupled inductors that may approximate an ideal transformer;

FIG. 5B is a circuit diagram of a circuit equivalent to the coupled inductors of FIG. 5A but reintroducing an ideal transformer;

FIGS. 6A and 6B are circuit diagrams corresponding to FIGS. 5A and 5B when the coupling is assumed to be maximal;

FIG. 7A is a circuit diagram of a hybrid lattice filter of FIG. 4, which uses acoustic resonators, and where two maximally coupled inductors replace the ideal transformer and an additional inductor is used;

FIG. 7B is a circuit diagram of the filter of FIG. 7A assuming an ideal transformer obtained by using the circuit equivalence between FIG. 6A and FIG. 6B;

FIG. 8A is a circuit diagram for a filter using a more generalized hybrid lattice topology assuming less than maximal coupling;

FIG. 8B is a circuit diagram of the filter of FIG. 8A using an equivalent T-network inductor substitution;

FIG. 9A is a circuit diagram of a filter corresponding to the filter of FIG. 8A with shields added;

FIG. 9B is a circuit diagram of a filter corresponding to the filter of FIG. 8B with a shield added;

FIG. 10 is a flowchart illustrating an exemplary process for forming a filter according to aspects of the present disclosure; and

FIG. 11 is a block diagram of a mobile terminal, which may include the filters of FIGS. 8A-9B according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses “transceiver” in a broad manner. Current industry literature uses transceiver both broadly to refer to a plurality of circuits that send and receive signals. Exemplary circuits may include a baseband processor, an up/down conversion circuit, filters, amplifiers, couplers, and the like coupled to one or more antennas. Likewise, some authors in the industry literature refer to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Aspects disclosed in the detailed description include hybrid lattice filters. In particular, a filter may be formed from a plurality of acoustic resonators and associated inductors. The inductors may be arranged such that they approach an ideal transformer to provide desired out-of-band rejection. Multiple stages of resonator structures may be chained together to form a filter with a desired response.

Transceivers of various sorts rely on filters to select desired signals (i.e., a passband or bandpass filter) or reject unwanted signals (stopband). In some cases, a single filter may perform both functions. There are many types of filters. Of interest for the present disclosure are lattice filters and hybrid lattice filters. These filters are of interest because of the generality of filtering functions that they can achieve. Specifically, these topologies, and more specifically topologies using acoustic resonators, provide relatively wideband bandpass filters since these topologies can compensate for static capacitances of acoustic resonators and circumvent the bandwidth limitations imposed by limited electromechanical coupling of the acoustic resonators. However, these topologies may require a balun or transformer for unbalanced operation, which is a hallmark of current wireless communication protocols. While capable of high levels of rejections assuming ideal baluns/transformers, nonidealities of real-world transformers may degrade performance.

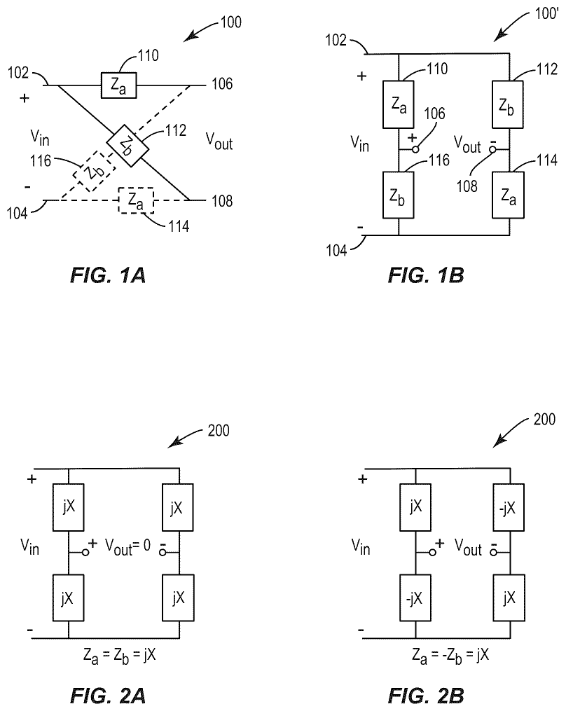

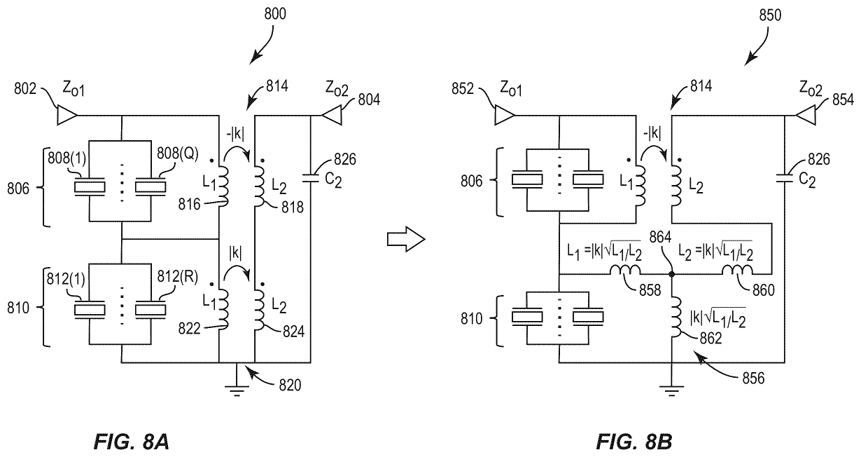

To assist in understanding the benefits of the present disclosure, a discussion of lattice and hybrid lattice circuits is provided, along with associated mathematical principles. This discussion allows unrelated equivalencies to be pointed out and then substituted back into practical applications to discuss a hybrid lattice filter according to the present disclosure. Thus, FIGS. 1A-7B provide more theoretical discussions, and a discussion of the practical implementations begins below with reference to FIG. 8A.

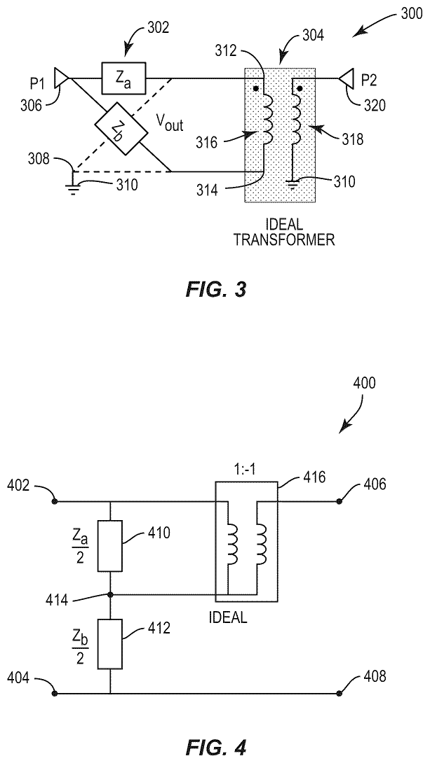

More specifically, an overview of a lattice filter is provided with reference to FIGS. 1A through 2B, along with an analysis of how such a lattice filter may be coupled to a transformer to provide unbalanced operation with reference to FIG. 3. Various equivalencies are explored in FIGS. 4-7B. A discussion of exemplary aspects of the present disclosure begins below with reference to FIG. 8A.

In this regard, FIG. 1A illustrates a block diagram of a lattice filter 100. The lattice filter 100 includes a positive input 102 and a negative input 104 that collectively form a Vin input. The lattice filter 100 further includes a positive output 106 and a negative output 108 that collectively form a Vout output. A first impedance 110 (Za) is located serially between the positive input 102 and the positive output 106. A second impedance 112 (Zb) is located serially between the positive input 102 and the negative output 108. Likewise, a third impedance 114 (Za), which is identical to the first impedance 110 (Za), is located serially between the negative input 104 and the negative output 108. Also, a fourth impedance 116 (Zb), which is identical to the second impedance 112 (Zb), is located serially between the negative input 104 and the positive output 106. Normally, Za and Zb are reactive to reduce filter loss.

Frequently, for simplicity, illustration of the third impedance 114 and the fourth impedance 116 is omitted or referenced using dotted lines. FIG. 1A shows the elements for completeness, but subsequent representations (e.g., the lattice filter 302 of FIG. 3) omit explicit illustrations of these impedances. FIG. 1B illustrates the same lattice filter 100 but presented in a balanced bridge form 100′.

It should be appreciated that the impedances Za, Zb are frequency dependent and may be expressed as Z(ω)=jX(ω). FIG. 2A illustrates a lattice filter 200 operating in a stopband when the impedances Za and Zb are equal (i.e., Za=Zb=jX) and Vout equals zero (Vout=0). Conversely, FIG. 2B illustrates the lattice filter 200 operating in a passband when Za=−Zb=jX.

In either case, stopband or passband, the filters 100, 200 are balanced. Most radio frequency systems are unbalanced since unbalanced systems are simpler in terms of routing compared to balanced systems. A balun may be used to convert the lattice filters 100, 200 to an unbalanced system. One possible balun is a transformer.

In this regard, FIG. 3 illustrates a filter system 300 having a lattice filter 302 coupled at Vout to an ideal transformer 304. The lattice filter 302 includes a positive input 306 coupled to a port P1. The lattice filter 302 also includes a negative input 308 coupled to a ground 310. The lattice filter 302 also includes a positive output 312 and a negative output 314. A first coil 316 of the ideal transformer 304 serially connects the positive output 312 to the negative output 314. The first coil 316 is inductively coupled to a second coil 318 of the ideal transformer 304. The second coil 318 is coupled to the ground 310 and to an output 320 with port P2.

Instead of adding a transformer such as ideal transformer 304 at an output of the lattice filter 302, a hybrid lattice filter 400, illustrated in FIG. 4, may be used. The hybrid lattice filter 400 is equivalent to the full lattice filter 100 of FIG. 1A. The hybrid lattice filter 400 includes a positive input 402 and a negative input 404 that collectively form a Vin input. The hybrid lattice filter 400 further includes a positive output 406 and a negative output 408 that collectively form a Vout output. A first impedance 410 (Za/2) and a second impedance 412 (Zb/2) are serially located between the positive input 402 and the negative input 404 with an intermediate node 414 therebetween. An ideal transformer 416 may be coupled to the positive output 406, the positive input 402, and the intermediate node 414. It should be appreciated that the hybrid lattice filter 400 remains unsuitable for physical implementation due to its reliance on an ideal transformer 416.

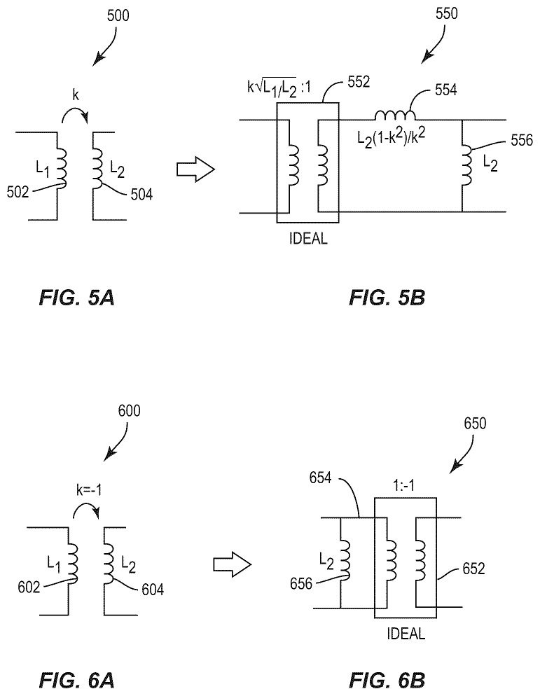

While an ideal transformer is not possible, a close approximation is a set 500 of two mutually coupled inductors 502, 504 (also referred to as L₁, L₂ respectively) having a coupling coefficient k as shown in FIG. 5A. A circuit 550 is shown in FIG. 5B that is a useful equivalent of the set 500 of inductors 502, 504, but uses an ideal transformer 552 and series inductor 554 and shunt inductor 556. The shunt inductor 556 is equal to L₂, while the equivalent value of the series inductor 554 is:

$$\frac{{L}_{2} ( 1 - {k}^{2} )}{{k}^{2}}$$

As a mathematical exercise, one can assume that the inductors 502, 504 are maximally coupled (i.e., k=1 or −1). For simplicity, assume k=−1. This assumption simplifies set 500 to set of coupled inductors 600 of FIG. 6A and circuit 550 to circuit 650 of FIG. 6B. Specifically, the set of coupled inductors 600 has inductors 602, 604. The circuit 650 has ideal transformer 652, but series inductor 654 simplifies to zero (0) and shunt inductor 656 remains the same as inductor 604.

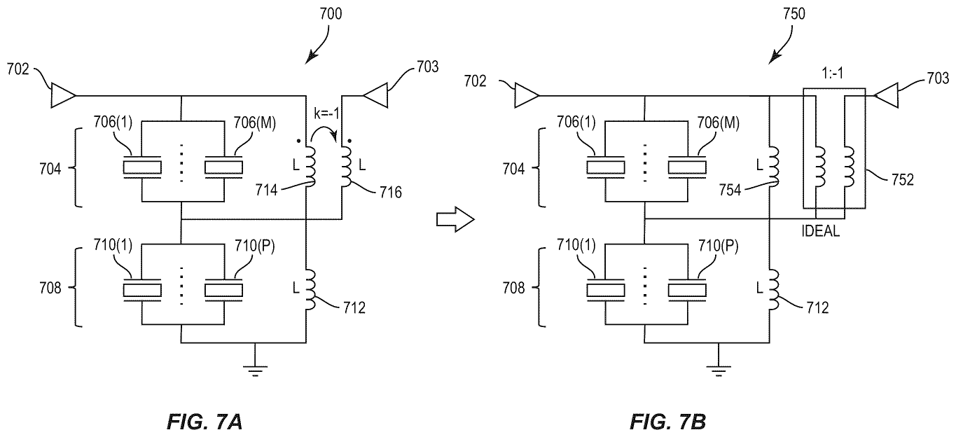

As noted above, use of acoustic resonators such as bulk acoustic wave (BAW) and surface acoustic wave (SAW) resonators in filters has a variety of desirable attributes. Accordingly, use of such resonators is possible in the impedance elements of FIG. 4. Generally, shunt inductors are used to cancel out static capacitances. When such a structure is plugged into FIG. 4, the result can be seen in equivalent filters 700, 750 shown in FIGS. 7A and 7B, respectively. More specifically, by using the circuit equivalence between the set of coupled inductors 600 and its equivalent circuit 650 in FIGS. 6A and 6B, respectively, it is seen that filter 700 in FIG. 7A and filter 750 in FIG. 7B are equivalent. More specifically, as shown in FIG. 7A, a filter 700 may include an input node 702 and an output node 703. A first impedance structure 704 is formed by acoustic resonators 706(1)-706(M). A second impedance structure 708 is formed by acoustic resonators 710(1)-710(P) with shunt inductor 712. The first impedance structure 704 does not have a shunt inductor because such inductance may be included in the coupled inductors 714, 716. Again, in filter 700, it is assumed that the inductors 714, 716 are maximally coupled (i.e., k=−1).

Equivalently, the filter 700 may be represented as filter 750, where the ideal transformer 752 and inductor 754 replace the inductors 714, 716 in accordance with the circuit equivalence between sets of coupled inductors 600 and their equivalent circuit 650 in FIGS. 6A and 6B, respectively.

A more realistic assumption is that |k|<1, and thus, asymmetric coupled inductors (i.e., L₁≠L₂) can be used to compensate for non-maximal mutual coupling to maintain equal port impedances between the input and output. Alternatively, if the inductors are identical, a capacitor may be added at the output to provide an additional impedance-matching option.

The resulting filter 800, illustrated in FIG. 8A, includes an input 802 (i.e., Zₒ₁), and an output 804 (i.e., Zₒ₂) with a first impedance structure 806 formed from acoustic resonators 808(1)-808(Q), and a second impedance structure 810 formed from acoustic resonators 812(1)-812(R). The first impedance structure 806 is parallel to a set 814 of coupled inductors 816, 818. The second impedance structure 810 is parallel to a second set 820 of coupled inductors 822, 824. An impedance-matching capacitor 826 may be present at the output 804 to provide additional impedance-matching options.

There are occasions when the coupling factor is greater than 0 (i.e., 0<k<1), in which case a set of inductors may be replaced with an equivalent T-network of inductors, as shown by filter 850 in FIG. 8B. The filter 850 includes an input 852 and an output 854. For the sake of illustration, the set 820 is replaced by T-network 856 of inductors 858, 860, 862, where inductor 862 is connected to intermediate node 864 between the inductors 858, 860.

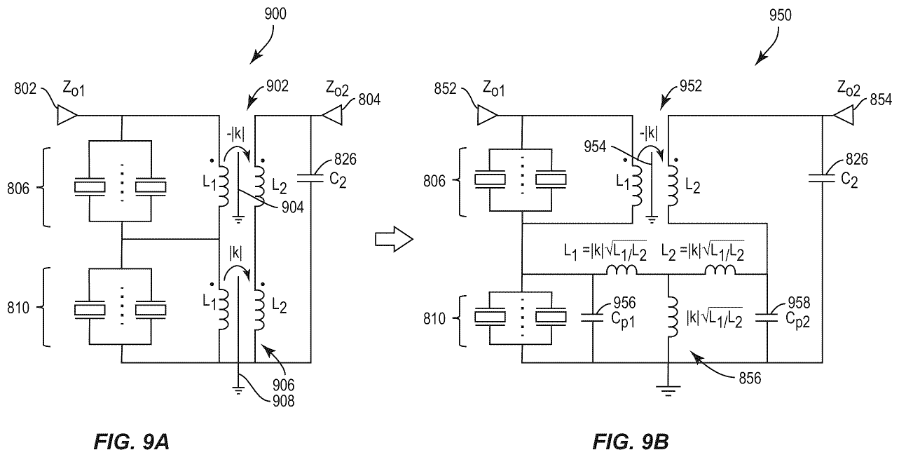

It should be appreciated that mutually coupled inductors are usually formed with closely spaced traces that generate some inter-capacitance. This capacitance may have an adverse effect on filter rejection. One option to reduce such cross-capacitance is the use of an electrostatic shield connected to ground between the inductor traces. This shield may result in additional capacitance to ground, but preliminary tests indicate that this additional capacitance to ground does not negatively impact performance. Use of such a shield is illustrated in FIGS. 9A and 9B, which are based on filters 800, 850 of FIGS. 8A and 8B.

In this regard, FIG. 9A illustrates filter 900 substantially similar to filter 800, but the set of inductors 902 includes a shield 904 coupled to ground. Likewise, the set of inductors 906 includes a shield 908 coupled to ground. The use of the shield allows the traces to be placed in closer proximity, resulting in higher mutual coupling and improved filter insertion loss.

FIG. 9B illustrates filter 950, substantially similar to filter 850, but the set of inductors 952 includes a shield 954. Capacitors 956 and 958 are added to maintain balance. However, these capacitors 956, 958 may be eliminated by absorbing the capacitance into the second impedance structure 810 or the capacitor 826, respectively.

While a single filter stage is shown in filters 800, 850, 900, and 950, it should be appreciated that these may be chained together to provide a desired performance.

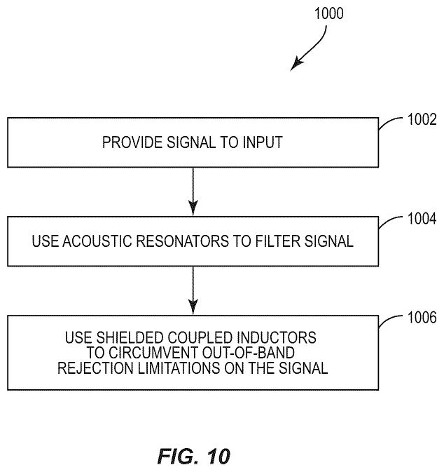

There is a corresponding process 1000 for using a filter according to the present disclosure, illustrated in FIG. 10. Specifically, the process 1000 begins by providing a signal to an input of the filter (block 1002). The process 1000 continues by using acoustic resonators to filter the signal (block 1004). Then the process 1000 uses shielded coupled inductors to circumvent out-of-band rejection limitations on the signal (block 1006).

The acoustic resonators, according to aspects disclosed herein, may be provided in or integrated into any transceiver device. While the above discussion assumes a wireless transceiver in a mobile communication device, the present disclosure is not so limited. Thus, examples of other transceiver devices, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

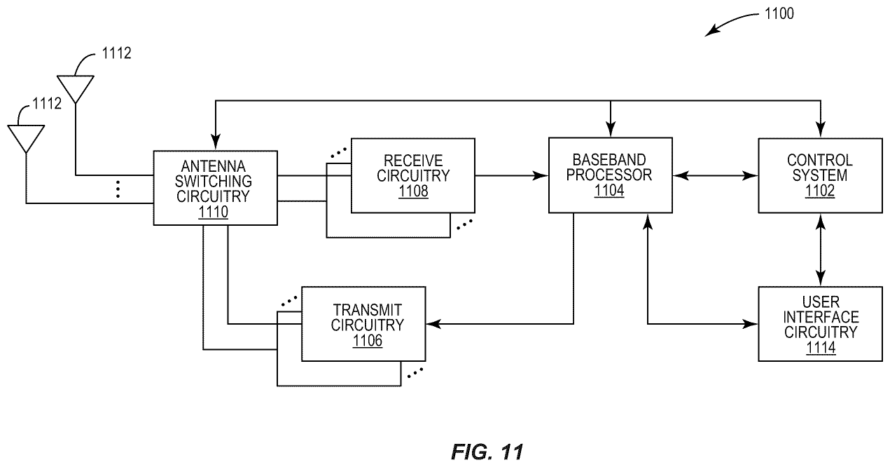

With reference to FIG. 11, the concepts described above may be implemented in various types of user elements 1100, such as mobile terminals, smart watches, tablets, computers, navigation devices, access points, and like wireless communication devices that support wireless communications, such as cellular, wireless local area network (WLAN), Bluetooth, and near field communications. The user elements 1100 will generally include a control system 1102, a baseband processor 1104, transmit circuitry 1106, receive circuitry 1108, antenna switching circuitry 1110, multiple antennas 1112, and user interface circuitry 1114. In a non-limiting example, the control system 1102 can be a field-programmable gate array (FPGA) or an application-specific integrated circuit (ASIC), as an example. In this regard, the control system 1102 can include at least a microprocessor(s), an embedded memory circuit(s), and a communication bus interface(s). The receive circuitry 1108 receives radio frequency signals via the antennas 1112 and through the antenna switching circuitry 1110 from one or more base stations. A low noise amplifier and a filter of the receive circuitry 1108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1104 processes the digitized received signal to extract the information or data bits conveyed in the received signal. This processing typically comprises demodulation, decoding, and error correction operations. The baseband processor 1104 is generally implemented in one or more digital signal processors (DSPs) and ASICs.

For transmission, the baseband processor 1104 receives digitized data, which may represent voice, data, or control information, from the control system 1102, which it encodes for transmission. The encoded data is output to the transmit circuitry 1106, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1112 through the antenna switching circuitry 1110 to the antennas 1112. The multiple antennas 1112 and the replicated transmit and receive circuitries 1106, 1108 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A filter comprising:
an input node;
an output node;
a first acoustic resonator coupled to the input node;
a first inductor coupled to the input node and electrically parallel to the first acoustic resonator;
a second inductor coupled to the output node and mutually coupled to the first inductor but electrically isolated therefrom; and
a second acoustic resonator serially coupled to the first acoustic resonator and a ground.

2. The filter of claim 1, further comprising an electrostatic shield between the first inductor and the second inductor, wherein the electrostatic shield is electrically isolated from both the first inductor and the second inductor and is connected to ground.

3. The filter of claim 1, further comprising a third inductor electrically parallel to the second acoustic resonator.

4. The filter of claim 3, further comprising a fourth inductor serially coupled to the second inductor and ground, the fourth inductor mutually coupled to the third inductor, but electrically isolated therefrom wherein mutual coupling between the third inductor and the fourth inductor is opposite to that between the first and second inductors.

5. The filter of claim 1, further comprising a capacitor coupling the output node to ground.

6. The filter of claim 1, where the first and second inductors are negatively coupled, and further comprising a T-network of inductors coupled to ground.

7. The filter of claim 6, wherein the T-network of inductors comprises a third inductor coupled to a node between the first acoustic resonator and the second acoustic resonator, a fourth inductor serially coupled between the second inductor and the third inductor forming an intermediate node therebetween, and a fifth inductor coupling the intermediate node to ground.

8. The filter of claim 1, further comprising a third acoustic resonator coupled to the input node and electrically parallel to the first acoustic resonator.

9. The filter of claim 8, further comprising a fourth acoustic resonator coupled to ground and electrically parallel to the second acoustic resonator.

10. The filter of claim 9, further comprising:
a third inductor mutually coupled to the second inductor and electrically isolated therefrom; and
an electrostatic shield between the second inductor and the third inductor.

11. The filter of claim 1, wherein the first acoustic resonator is a bulk acoustic wave (BAW) resonator.

12. A method of operating a filter comprising:
providing a signal to an input node;
filtering the signal with a plurality of acoustic resonators; and
using shielded mutually coupled inductors to circumvent out-of-band rejection limitations on the signal.

13. The method of claim 12, further comprising generating a filtered signal at an output node.

14. The method of claim 12, wherein using shielded mutually coupled inductors comprises using a shield that is coupled to ground.

15. A communication device comprising:
a transceiver comprising a filter, the filter comprising:
an input node;
an output node;
a first acoustic resonator coupled to the input node;
a first inductor coupled to the input node and electrically parallel to the first acoustic resonator;
a second inductor coupled to the output node and mutually coupled to the first inductor but electrically isolated therefrom; and
a second acoustic resonator serially coupled to the first acoustic resonator and a ground.

16. The communication device of claim 15, further comprising an electrostatic shield between the first inductor and the second inductor, wherein the electrostatic shield is electrically isolated from both the first inductor and the second inductor.

17. The communication device of claim 15, further comprising a third inductor electrically parallel to the second acoustic resonator.

18. The communication device of claim 17, further comprising a fourth inductor serially coupled to the second inductor and ground, the fourth inductor mutually coupled to the third inductor, but electrically isolated therefrom.

19. The communication device of claim 15, further comprising a capacitor coupling the output node to ground.

20. The communication device of claim 15, wherein the communication device is a wireless communication device.
